(19) United States
(12) Patent Application Publication
(10) Pub. No.: US 2005/0270109 A1
(43) Pub. Date: Dec. 8, 2005

(54) Clock oscillator for reducing power consumption

(76) Inventor: Sang-Hoon Ha, Chungcheongbuk-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/126,706

(22) Filed: May 10, 2005

(30) Foreign Application Priority Data
Apr. 30, 2004 (KR) 2004-0030568

(51) Int. Cl. H03B 1/00

(52) U.S. Cl. 331/57

(57) ABSTRACT

A clock generator for use in a system on chip (SoC) includes a crystal oscillating unit, whose input terminal and an output terminal is respectively coupled to one terminal and the other terminal of a quartz vibrator, for generating a first clock; a ring oscillating unit for receiving an output of the crystal oscillating unit to thereby generate a second clock; and a selecting unit for selectively operating the crystal oscillating unit and the ring oscillating unit according to a power mode of the SoC to thereby use one of the first clock and the second clock as an operational clock of the SoC.

### FIELD OF INVENTION

The present invention relates to a clock generation circuit for use in a system on chip (SoC); and, more particularly, to a clock generation circuit for reducing a power consumption.

### DESCRIPTION OF PRIOR ART

Generally, a system on chip (SoC) has been developed for integrating all the functions of an end product, e.g., a computer system, in a single chip. That is, the SoC integrates all components of the computer system into the single chip. For instance, the SoC for use in a communication system includes a microprocessor, a digital signal processing (DSP), a random access memory (RAM) and a read only memory (ROM). Since a size of a system can be reduced by using the SoC, the SoC is employed in a portable electronic device.

In recent days, a market of portable electronic devices is continuously expanded. Accordingly, reducing a power consumption of a portable electronic device becomes an important element for producing competitive goods.

The SoC includes three different power modes, i.e., an active mode, an idle mode and a stop mode, for reducing a power consumption. The power mode of the SoC is determined by a clock signal.

When a clock signal is provided to both a core region and a peripheral region, the SoC is in the active mode. At the active mode, the SoC is normally operated.

However, at the idle mode, the clock signal is provided to only the peripheral region. At the idle mode, a power consumption of the core region can be reduced. In addition, a frequency of the clock signal provided to the peripheral region is not required to be such exact as a frequency of the clock signal provided to the core region.

When the clock signal is provided to neither the core region nor the peripheral region, the SoC is in the stop mode. At the stop mode, the SoC is not operated.

FIG. 1 is a schematic circuit diagram showing a conventional crystal (X-tal) oscillation circuit 10.

Referring to FIG. 1, a crystal (X-tal) 40 located at outside of a chip and an oscillator included in the chip generate a sinusoidal signal together. The sinusoidal signal outputted from the conventional crystal oscillation circuit 10 is converted to a square wave by an inverter (not shown) connected to an output terminal of the conventional crystal oscillation circuit 10.

That is, an input signal outputted from the crystal 40 is inputted to an amplifier 20 through an input terminal Xin to be converted as the sinusoidal signal. Then, the sinusoidal signal is passed to an output terminal OUT of the conventional crystal oscillation circuit 40 and an output terminal Xout of the crystal 40. A feedback resistor 30 serves to increase a gain of the amplifier 20. The feedback resistor 30 has a resistance of tens of K ohms.

Since the input signal inputted to the input terminal Xin is very small, each size of a p-type metal oxide semiconductor (PMOS) transistor 21 and an n-type metal oxide semiconductor (NMOS) transistor 22 included in the amplifier 20 is designed to be large. Accordingly, due to the large sizes of the PMOS transistor 21 and the NMOS transistor 22, a power consumption is increased.

Meanwhile, generally, the conventional crystal oscillator 10 can generate a clock signal having a very exact frequency. Indeed, a clock signal inputted to the core region is required to have a very exact frequency. However, in the peripheral region, a clock signal is not required to have such an exact frequency.

Even when the chip is in the idle mode where the clock signal is inputted to only the peripheral region, the input signal inputted to the input terminal Xin is amplified by the amplifier 20 to be outputted to the output terminal Xin, i.e., the conventional crystal oscillator 10 is operated to generate the clock signal having a very exact frequency. Since the gain of the amplifier 20 is very large having tens of decibels (dB), a quite large amount of power is required. Accordingly, a power is unnecessarily consumed at the idle mode.

That is, even when the chip is in the idle mode, the conventional crystal oscillator unnecessarily consumes a power to generate the clock signal having an exact frequency not required at the idle mode. Accordingly, it is hard to reduce a power consumption of the chip.

### SUMMARY OF INVENTION

It is, therefore, an object of the present invention to provide a clock generator for use in a system on chip (SoC) in order to reduce a power consumption.

In accordance with an aspect of the present invention, there is provided a clock generator for use in a system on chip (SoC) including a crystal oscillating unit, whose input terminal and an output terminal is respectively coupled to one terminal and the other terminal of a quartz vibrator, for generating a first clock; a ring oscillating unit for receiving an output of the crystal oscillating unit to thereby generate a second clock; and a selecting unit for selectively operating the crystal oscillating unit and the ring oscillating unit according to a power mode of the SoC to thereby use one of the first clock and the second clock as an operational clock of the SoC.

### BRIEF DESCRIPTION OF THE DRAWINGS

The above and other objects and features of the present invention will become apparent from the following description of preferred embodiments taken in conjunction with the accompanying drawings, in which:

FIG. 1 is a schematic circuit diagram showing a conventional crystal oscillation circuit; and

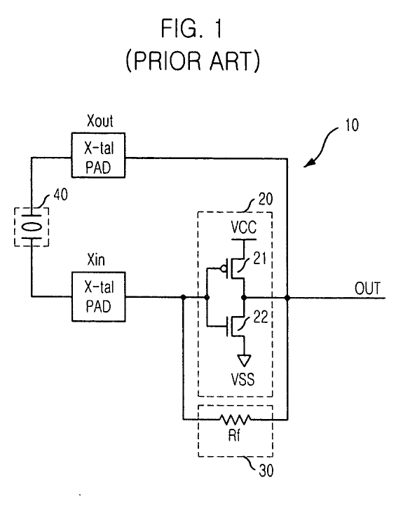

FIG. 2 is a schematic circuit diagram showing a clock generator in accordance with a preferred embodiment of the present invention.

### DETAILED DESCRIPTION OF INVENTION

Hereinafter, a clock generator in accordance with the present invention will be described in detail referring to the accompanying drawings.

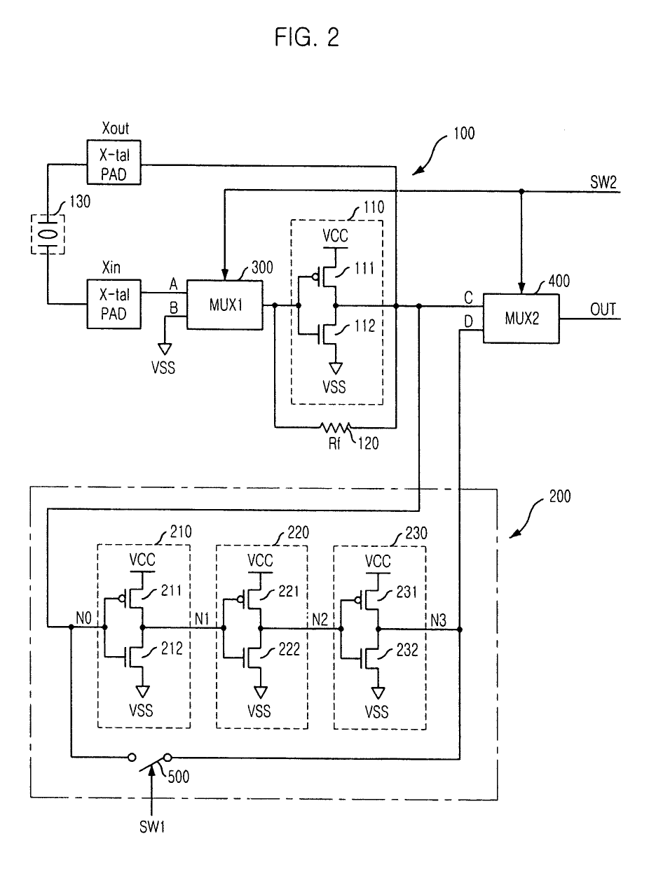

FIG. 2 is a schematic circuit diagram showing a clock generator in accordance with a preferred embodiment of the present invention.

As shown, the clock generator includes a crystal oscillator 100, whose input terminal and an output terminal are respectively coupled to one terminal and the other terminal of a quartz vibrator (X-tal) 130 located at outside of a chip, for generating a clock having a particular frequency; a ring oscillator 200 for receiving an output of the crystal oscillator 100, wherein an output of the ring oscillator 200 is feed-backed to an input of the ring oscillator 200; and a selection unit for selectively operating the crystal oscillator 100 and the ring oscillator 200.

Herein, the selection unit includes a switch 500 for selectively connecting the output of the ring oscillator 200 to the input of the ring oscillator 200 in response to a first control signal SW1; a first selector 300 for connecting one of one terminal of the quartz vibrator 130 and a ground voltage VSS to the ring oscillator 100; and a second selector 400 for selecting one of the output of the ring oscillator 200 and the output of the crystal oscillator 100 in response to a second control signal SW2.

The crystal oscillator 100 generates a clock having a very exact frequency. The quartz vibrator 130, an amplifier 100 and a feed-back resistor 120 generate a sinusoidal signal. Then, the sinusoidal signal is converted to a square wave, i.e., the clock, to be used as an internal clock of a system on chip (SoC). The clock generated by the crystal oscillator 100 is used by the SoC when the SoC is in an active mode.

The ring oscillator 200 includes a first to a third inverters 210 to 230 connected in series. An output of the third inverter 230 is feed-backed to an input of the first inverter 210. The first inverter 210 includes a first p-type metal oxide semiconductor (PMOS) transistor 211 and a first n-type metal oxide semiconductor (NMOS) transistor 212. The second inverter 220 includes a second PMOS transistor 221 and a second NMOS transistor 222. The third inverter 230 includes a third PMOS transistor 231 and a third NMOS transistor 232.

When a voltage loaded on a first node NO is in a logic high level, the first NMOS transistor 212 is turned on. Then, a voltage loaded on a second node N1 is in a logic low level. Therefore, the second PMOS transistor 221 is turned on, whereby a third node N2 is in a logic high level. Then, the third NMOS transistor 232 is turned on and, thus, the output of the third inverter 230 is in a logic low level.

Thereafter, the output of the third inverter 230 is feed-backed to the first node NO. Accordingly, the first PMOS transistor 211, the second NMOS transistor 222 and the third PMOS transistor 230 are sequentially turned on. Thus, the output of the third inverter 230 becomes in a logic high level. That is, a sinusoidal signal outputted from the ring oscillator 200 has a period corresponds to the time elapsed while the output of the ring oscillator 200 changes from an initial logic high level to a next logic high level.

At an idle mode, the output of the ring oscillator 200 is used as the internal clock of the SoC. That is, at the idle mode, since the SoC does not require such an accurate frequency of a clock, instead of the output of the crystal oscillator 100, the output of the ring oscillator 200 is used as the internal clock of the SoC for reducing a power consumption.

For selectively operating the ring oscillator 200 and the crystal oscillator 100 according to a power mode, the first and the second selectors 300 and 400 are provided. Each of the first and the second selectors 300 and 400 is a multiplexer controlled by the second control signal SW2.

At the active mode, a terminal A of the first selector 300 and a terminal C of the second selector 400 are selected to thereby use the output of the crystal oscillator 100 as the internal clock of the SoC. On the contrary, at the idle mode, a terminal B of the first selector 300 and a terminal D of the second selector 400 are selected to thereby use the output of the ring oscillator 200 as the internal clock of the SoC.

Meanwhile, the switch 500 is turned off at the active mode and is turned on at the idle mode according to the first control signal SW1 to thereby control an operation of the ring oscillator 200.

When the terminal B of the first selector 300 and the terminal D of the second selector 400 are selected, the ground voltage VSS is connected to an input terminal of the crystal oscillator 100. Thus, a voltage level of the input terminal of the crystal oscillator 100 is fixed to a logic low level and a voltage level of the output terminal of the crystal oscillator 100 is fixed to a logic high level. That is, the crystal oscillator 100 is disabled.

Meanwhile, since the ring oscillator 200 is operated by receiving the output of the crystal oscillator 100, a frequency of a clock generated by the ring oscillator 200 is same to that of a clock outputted from the output terminal of the crystal oscillator 100. The clock generated by the ring oscillator 200 is inputted to the terminal D. That is, the ring oscillator 200 is operated as a latch circuit and thus, the clock generated by the ring oscillator 200 has a same frequency as that of the clock generated by the crystal oscillator 100 and is inputted to the terminal D to be outputted through an output terminal OUT.

In comparison with a size of a fourth PMOS transistor 111 or a fourth NMOS transistor 112 included in the crystal oscillator 100, each size of transistors included in the ring oscillator 200 is very small. Accordingly, the ring oscillator 200 consumes less power in comparison with the crystal oscillator 100.

Therefore, when the ring oscillator 200 is operated and the crystal oscillator 100 is disabled at the idle mode, a power consumption can be reduced since each of the fourth PMOS transistor 111 and the fourth NMOS transistor 112 is in a constant state.

As a result, a power consumption of a SoC can be reduced by using the clock generator in accordance with the present invention.

While the present invention has been described with respect to the particular embodiments, it will be apparent to those skilled in the art that various changes and modifications may be made without departing from the spirit and scope of the invention as defined in the following claims.

1. A clock generation apparatus for use in a system on chip (SoC), comprising:
a crystal oscillating means, whose input terminal and an output terminal is respectively coupled to one terminal and the other terminal of a quartz vibrator, for generating a first clock;
a ring oscillating means for receiving an output of the crystal oscillating means to thereby generate a second clock; and
a selecting means for selectively operating the crystal oscillating means and the ring oscillating means according to a power mode of the SoC to thereby use one of the first clock and the second clock as an operational clock of the SoC.

2. The clock generation apparatus as recited in claim 1, wherein the selecting means operates the crystal oscillating means at an active power mode and operates the ring oscillating means at an idle power mode.

3. The clock generation apparatus as recited in claim 1, wherein the ring oscillation means includes a plurality of inverters connected in series, wherein an output of a last inverter of the plurality of inverters is selectively feed-backed to an input of a first inverter of the plurality of inverters.

4. The clock generation apparatus as recited in claim 3, wherein the selecting means includes:
a switch for selectively feed-backing the output of the last inverter to the input of the first inverter in response to a first control signal;
a first selector for connecting one of a ground voltage and one terminal of the quartz vibrator to the crystal oscillating means according to a second control signal; and
a second selector for selecting one of an output of the crystal oscillating means and an output of the ring oscillating means.

5. The clock generation apparatus as recited in claim 4, wherein each of the first selector and the second selector is a multiplexer.

6. The clock generation apparatus as recited in claim 1, wherein a size of a metal oxide semiconductor (MOS) transistor included in the ring oscillating means is smaller than a size of a MOS transistor included in the crystal oscillating means.
